(19) United States
(12) Patent Application Publication
(10) Pub. No.: US 2010/0190294 A1
(43) Pub. Date: Jul. 29, 2010

(54) METHODS FOR CONTROLLING WAFER AND PACKAGE WARPAGE DURING ASSEMBLY OF VERY THIN DIE

(76) Inventor: Margaret R. Simmons-Matthews, Richardson, TX (US)

Correspondence Address: TEXAS INSTRUMENTS INCORPORATED, P O BOX 655474, M/S 3999, DALLAS, TX, 75265, US

(21) Appl. No.: 12/694,783

(22) Filed: Jan. 27, 2010

Related U.S. Application Data
(60) Provisional application No. 61/148,234, filed on Jan. 29, 2009.

(51) Int. Cl. H01L 21/50

(52) U.S. Cl. 438/108; 257/E21.499

(57) ABSTRACT

Various exemplary embodiments provide materials and methods for flip-chip packaging a thin TSV semiconductor die, which uses other packaging components, for example, a second die, as a packaging carrier to attach the thin TSV semiconductor die to a package substrate. Warpage and mis-alignment can be reduced or eliminated during the packaging process of the thin TSV die.

### DESCRIPTION OF THE INVENTION

### Related Applications

This application claims priority from U.S. Provisional Patent Application Ser. No. 61/148,234, filed Jan. 29, 2009, which is hereby incorporated by reference in its entirety.

### FIELD OF THE INVENTION

The invention relates generally to semiconductor device packaging and, more specifically, to methods for controlling wafer and package warpage during assembly of thin semiconductor dies.

### BACKGROUND OF THE INVENTION

One form of packaging for semiconductor devices is known as flip-chip packaging. Conventional flip-chip packaging methods include steps of: singulating flip-chip dies from a die wafer; placing a flip-chip die with its bump-side down on a package substrate; making a flip-chip joint between the die and the package substrate; and placing underfill material between the die and the package substrate.

When the flip-chip die contains TSVs (through silicon vias) and can accommodate a second die to be packaged thereon, conventional packaging methods then include steps of: singulating flip-chip TSV dies from a die wafer; placing a flip-chip TSV die with its bump-side down and TSV-side up on a package substrate; making a flip-chip joint between the TSV die and the package substrate; placing underfill material between the TSV die and the package substrate; attaching a second die to the TSV-side of the TSV die; and placing underfill material between the TSV die and the second die.

That is, conventional packaging of TSV die includes first attaching the TSV die to the package substrate and then attaching the second die to the assembled TSV die on the package substrate. Electrical interconnection terminals may be present on top side of the TSV die in order to electrically connect with the second die; and may also be present on bottom side of the TSV die in order to make a flip-chip interconnect with the package substrate.

### SUMMARY OF THE INVENTION

In a conventional flip-chip packaging process that vertically packages a packaging component on a TSV semiconductor die containing through silicon vias (TSVs), the packaging component must be assembled after the TSV semiconductor die has been attached onto a package substrate. However, the conventional flip-chip packaging process presents handling difficulties, warpage issues, and mis-alignment issues.

For example, the semiconductor die that contains TSVs requires a very thin die thickness as known to one of ordinary skill in the art, for example, having a thickness of less than about 100 μm. The very thin TSV semiconductor die is mechanically flexible. Additionally, having electrical interconnection terminals on both top and bottom sides of the very thin TSV die makes the flexible die even more difficult to handle during the packaging process. For example, the TSV die can have a high terminal density on both sides, such as, having about 1200 terminals on each side of a 25 mm² die.

Further, the mechanical handling difficulties of the die and/or the topological complexity of the package substrate may result in warpage and mis-alignment of the TSV semiconductor die and the package substrate especially when exposed to elevated temperatures. Even further, TSV semiconductor dies may contain dense arrays of TSVs that require high location precision, and interconnect mis-alignment between the TSV die and the packaging component is often a problem. Furthermore, warpage and mis-alignment can be caused by TEC (thermal expansion coefficient) mismatches between adjacent components of the packaged semiconductor device. Consequently, any handling problems, warpage issues and/or mis-alignment issues may result in shorted or open TSV connections.

Various methods have been attempted in order to overcome the handling difficulties, the warpage issues, and the mis-alignment issues occurring in the conventional thin die packaging process. For example, one conventional method includes making a suitable selection of substrate materials for the flip-chip packaging of thin TSV dies. In one example, ceramic substrates can be used as the package substrate to provide surface flatness and low thermal expansion coefficient (TEC). However, ceramic substrates are expensive and are not suitable for small-sized devices due to the nature of ceramic materials.

Other conventional methods to overcome these problems for assembling thin TSV dies that have electrical interconnection terminals on both sides include use of an intermediate carrier or an interposer. For example, an intermediate carrier can be applied on one side of the thin TSV die, before the opposite side of TSV die is assembled onto the package substrate. After the removal of the intermediate carrier from the assembled TSV die, other packaging components, for example, a second die, can then be assembled onto the TSV die. However, the use of the intermediate carrier increases processing time and adds manufacturing cost.

The Applicants have developed new methods for flip-chip packaging TSV semiconductor dies in order to overcome the handling difficulties, the warpage issues, and/or the mis-alignment issues occurring in the conventional flip-chip packaging process. The new methods can utilize conventional equipment, thus avoiding additional manufacturing cost and increased processing time.

The disclosed flip-chip packaging methods can include, for example, first assembling one or more other packaging components with the TSV semiconductor die to form a packaging stack and then flip-chip packaging the TSV die-containing packaging stack onto the package substrate. That is, the other packaging components can be used as a packaging carrier for the flip-chip packaging of the thin TSV semiconductor die onto the package substrate.

The disclosed flip-chip packaging methods can be distinguished from conventional flip-chip packaging methods where a packaging component is assembled on a thin TSV die that is already attached to the package substrate.

The packaging components can include, for example, a second die, a component stack, and/or a component molded strip. Because the packaging components often have a matched TEC to the TSV semiconductor die, warpage and mis-alignment caused by TEC mismatches can be avoided, as disclosed herein.

In addition, the packaging components can have a controllable thickness, for example, of more than about 100 μm. Because of the formation of the packaging stack that includes the packaging components stacked on the TSV semiconductor die, the thin TSV flip-chip die can be mechanically stabilized and resistant to flexing or warping during its subsequent attachment to the package substrate.

Further, during the disclosed flip-chip packaging process, underfill materials can be applied to stabilize interconnections and absorb stress between adjacent components of the packaged device, for example, between the packaging components and the TSV die and/or between the TSV die and the package substrate.

The technical advances represented by the present teachings, as well as the aspects thereof, will become apparent from the following description of the exemplary embodiments of the invention, when considered in conjunction with the accompanying drawings and the novel features set forth in the appended claims.

### BRIEF DESCRIPTION OF THE DRAWINGS

The accompanying drawings, which are incorporated in and constitute a part of this specification, illustrate embodiments of the invention and together with the description, serve to explain the principles of the invention.

FIGS. 1A-1F depict an exemplary method for flip-chip packaging a TSV semiconductor die in accordance with various embodiments of the present teachings.

FIG. 2 depicts a flip-chip packaged device in accordance with various embodiment of the present teachings

FIGS. 3A-3C depict an additional exemplary method for flip-chip packaging a TSV semiconductor die in accordance with various embodiments of the present teachings.

It should be noted that some details of the figures have been simplified and are drawn to facilitate understanding of the inventive embodiments rather than to maintain strict structural accuracy, detail, and scale.

### DESCRIPTION OF THE EMBODIMENTS

Various exemplary embodiments provide materials and methods for flip-chip packaging a thin semiconductor die. In embodiments, one or more other packaging components, for example, a second die, can be assembled on the thin semiconductor die and can be used as a packaging carrier for attaching the thin semiconductor die to a package substrate. Mis-alignment and warpage can then be reduced or eliminated during the disclosed flip-chip packaging process. Reference will now be made in detail to exemplary embodiments of the invention, examples of which are illustrated in the accompanying drawings. Wherever possible, the same reference numbers will be used throughout the drawings to refer to the same or like parts.

As disclosed herein, the term “TSV semiconductor die” or “TSV die” refers to a semiconductor die containing a plurality of through silicon vias (TSVs) or TSV arrays. In embodiments, the TSV semiconductor die can include a dense array of TSVs, for example, including about 100 to about 1000 TSVs per die. In embodiments, each TSV of the TSV die can have a diameter of less than about 10 μm and a TSV pitch of less than about 50 μm. In embodiments, the TSV semiconductor die can be a thin semiconductor die, for example, having a thickness of about 100 μm or less.

As disclosed herein, the TSV semiconductor die can include, but is not limited to, a microprocessor, a digital signal processor, a radio frequency chip, a MEMS chip, a memory, a microcontroller, an application specific integrated circuit, or a combination thereof.

As disclosed herein, other packaging components can include, for example, various IC (integrated circuit) components packaged with the TSV semiconductor die. In embodiments, the packaging components can include, for example, a second die, an IC (integrated circuit) stack, an IC molded strip, a passive component, a circuit board, a system-on-a-chip, a ball grid array (BGA), a microprocessor, a digital signal processor, a radio frequency chip, a MEMS chip, a memory, a microcontroller, and/or other ICs known to one of ordinary skill in the art.

In embodiments, the packaging components can be packaged on the thin TSV semiconductor die and can be used as a carrier for the packaging of TSV die. In embodiments, the packaging components and the TSV semiconductor die can have the same or different shapes and/or sizes. In embodiments, the packaging components can include a heterogeneous IC component. In embodiments, the packaging components may or may not contain TSVs.

As disclosed herein, the term “packaging stack” refers to a stack including the above described packaging components stacked on the TSV semiconductor die, wherein the packaging components can be used as a carrier for a subsequent packaging of the thin TSV semiconductor die onto a package substrate.

As disclosed herein, the term “package substrate” refers to a base substrate or a panel for the flip-chip packaging, as known to one of ordinary skill in the art. In embodiments, the package substrate can be made of various materials, organic or inorganic. In embodiments, the package substrate can include, for example, a glass epoxy substrate including a glass-fiber-reinforced epoxy resin, such as FR4, a bismaleimide triazine (BT) substrate, a lead frame substrate, a silicon wafer or other substrates formed from suitable materials. For example, the package substrate can be formed from thinner substrates, such as polyimide or ceramic films for high temperature applications, or formed from thicker substrates, such as multilayer substrates (i.e., laminates). In embodiments, the package substrate can be in a form of a strip, a singulated piece, or a reel-to-reel format. In one embodiment, the package substrate can be rectangular in shape with dimensions approximately ten inches wide by twelve inches long; or with any suitable shape and any suitable size.

In embodiments, various conductive pads or bonding pads can be used to facilitate electrical interconnection between components of the packaging. In embodiments, the bonding pads can include, e.g., a layer of one or more metals including, but not limited to, copper, aluminum, gold, silver, nickel, tin, platinum, or combinations thereof. The bonding pads can include laminated and/or plated metal(s). The bonding pad can be patterned metal layer(s) and can include one or more circuit traces within the package radiating outward from it. In one embodiment, the bonding pad can be a copper pad and/or can have a combination of copper, nickel and gold. In other embodiments, the bonding pad can have a thickness of, e.g., about 18 microns to about 25 microns.

In embodiments, conductive bumps can be formed on one side of a semiconductor die in a flip-chip packaging system. For example, conductive bumps can be formed in through holes of a photo-resist layer formed on the semiconductor die followed by a removal of the photo-resist layer. In embodiments, conductive bumps can use the same or similar materials and methods as for the bonding pads and also for TSVs of the thin semiconductor die. In embodiments, conductive bumps can include, for example, solder, copper, copper plus solder or solder-loaded epoxy paste. In embodiments, conductive bumps can include plated metal bumps. In embodiments, conductive bumps of the semiconductor die can provide electrical interconnections with a package substrate, for example.

As disclosed herein, underfill techniques can be used in the disclosed flip-chip packaging process. For example, to enhance the joint integrity between adjacent packaging components, an underfill material can be introduced in a gap, for example, between the packaging component and the TSV semiconductor die, between layers of the packaging component, and/or between the TSV semiconductor die and the package substrate. Underfill materials can provide joint reliability by reducing stresses from the joining of, for example, solder bumps of the TSV semiconductor die to the solder pads on the package substrate.

In embodiments, the underfill materials can include, for example, an epoxy resin, although other suitable types of materials can be used as known to one of ordinary skill in the art. In embodiments, the underfill materials can be a continuous layer applied, for example, post attachment by a capillary underfill, during attachment by a non-conductive underfill paste, and/or prior to attachment by laminating an underfill film on the die.

In embodiments, the bonding or coupling between components, for example, between the packaging component and the TSV semiconductor die, between layers of the packaging component, and/or between the TSV semiconductor die and the package substrate, can be performed using, for example, thermo-compression bonding, solder reflow bonding, or other suitable bonding or attachment technologies.

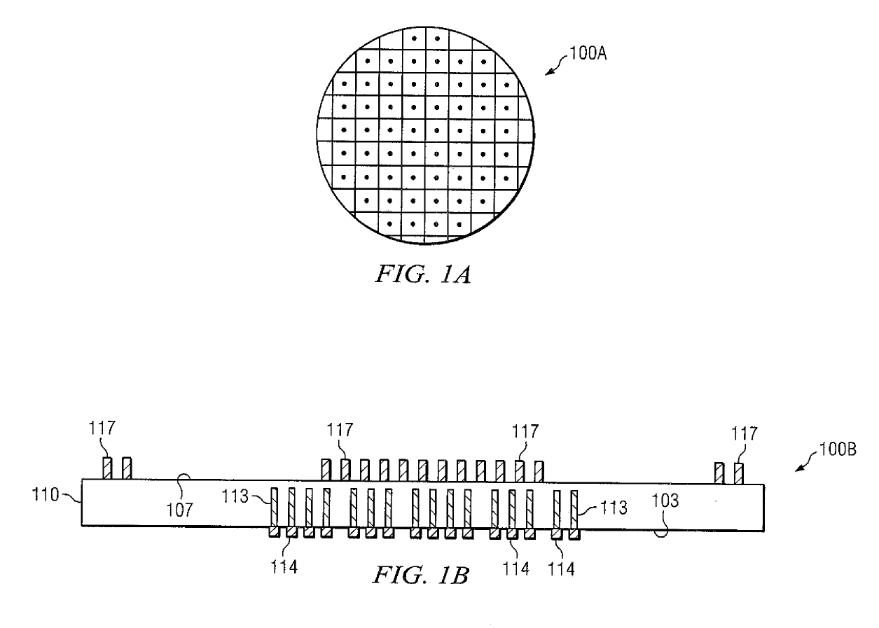

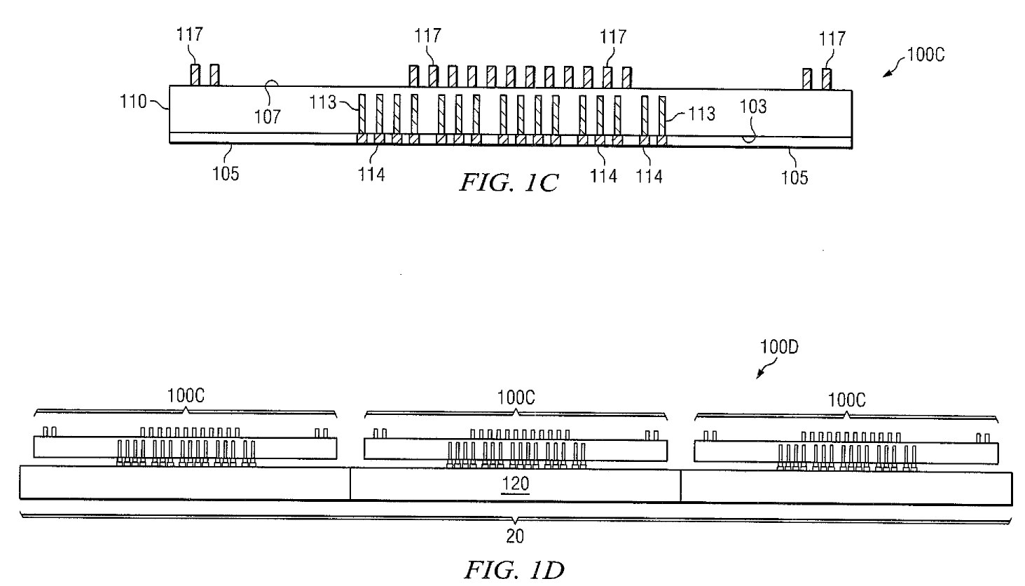

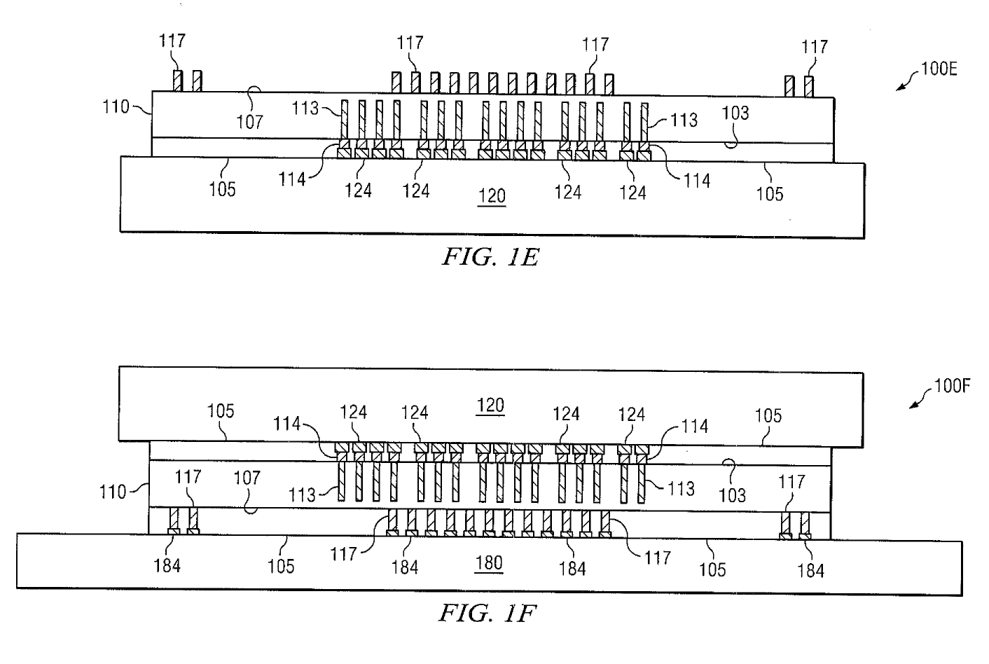

FIGS. 1A-1F depict an exemplary method for flip-chip packaging a TSV semiconductor die in accordance with various embodiments of the present teachings. In this example, a second semiconductor die can be used as the packaging component and stacked onto a TSV semiconductor die prior to its flip-chip packaging onto a package substrate.

In FIG. 1A, a TSV semiconductor wafer 100A can be provided. The TSV semiconductor wafer 100A can include a plurality of TSV semiconductor dies 100B as shown in FIG. 1B. The TSV die 110 can include a plurality of TSVs 113 buried within the die. Each TSV die 110 can include a TSV-side 103 and a bump-side 107. For example, the TSV-side 103 can expose TSVs 113 with each TSV connecting to a bonding pad 114. The bump-side 107 of the TSV die 110 can include a plurality of conductive bumps 117, for example, copper pillars, on an opposing side of the exposed TSVs 113 along with bonding pads 114.

In embodiments, the TSV wafer 100A can be singulated into discrete TSV dies 1008. For example, the wafer 100A can first be prepared to include buried TSVs 113 and conductive bumps 117, and attached to a wafer carrier. The wafer 100A can then be thinned to expose each TSV 113, removed from the wafer carrier, and singulated into discrete TSV dies 100B. In embodiments, the singulation process can be performed by, for example, a wafer sawing process, or other known methods. Each TSV die 100B can then be picked from the sawn wafer.

In FIG. 1C, underfill material 105, for example, an underfill film, a capillary underfill, or an underfill paste, can be applied on the TSV-side 103 of the TSV die 110 that contains bonding pads 114.

In FIG. 1D, the TSV device 100C can be placed or stacked on a packaging component, for example, a second die, such as a corresponding die 120 of a second die wafer 20. The TSV-side 103 of the device 100C can be attached to the second die 120. In embodiments, the second die 120 can include a plurality of bonding pad 124 to electrically connect the TSV die 110 through the TSV bonding pads 114.

Optionally, the bonding pad side of the second die 120 can also include an underfill material 105 applied prior to the placement of the TSV die 110 on the second die wafer 20.

In embodiments, a joint or an interconnection can be formed between the TSV die 110 and the corresponding die 120 of the second die wafer 20 by a process of, for example, solder reflow bonding, thermo-compression bonding, or other bonding techniques.

In FIG. 1E, the second die wafer 20 can be singulated into discrete dies, for example, using wafer sawing or other known techniques. The device 100E shows that underfill materials can fill the gap between the TSV die 110 and the second die 120. The flip-chip TSV die 110 and the second die 120 can be electrically interconnected by connecting corresponding bonding pads 114 and 124. The device 100E can also be referred to as a packaging stack.

In FIG. 1F, the packaging stack 100E can be flipped and attached to a package substrate 180, such as a panel. As shown, the conductive bumps 117 of the TSV die 110 can be electrically connected with bonding pads 184 of the package substrate 180 to provide a flip-chip interconnect. In embodiments, underfill materials 105 can fill the gap between the flip-chip TSV die 110 of the packaging stack 100E and the package substrate 180 to provide mechanical reliability of the flip-chip interconnect. The flip-chip interconnect can be formed by, for example, solder reflow bonding, thermo-compression bonding, or other technique as known for flip-chip bonding.

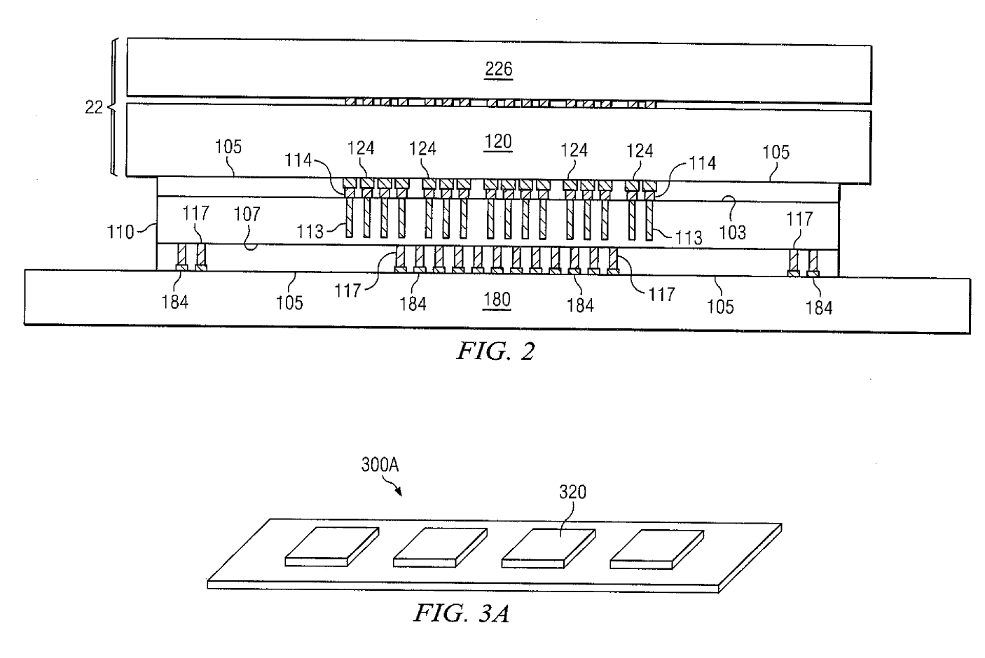

In embodiments, various other packaging components can be assembled with the TSV die to form a packaging stack for a subsequent flip-chip packaging of the TSV die. For example, the second die wafer 20 or the second die 120 can be replaced by a packaging component of a die stack including homogeneous dies that may be interconnected by TSVs. For example, FIG. 2 depicts a flip-chip packaged device including a die stack 22 vertically assembled on the TSV die 110 in accordance with various embodiment of the present teachings.

As similarly described in FIGS. 1A-1F, the packaging process of the device 200 can be performed by, for example, attaching the TSV-side 107 of the TSV device 100C to each die stack 22 of a die stack wafer (not shown) to form a packaging stack. After singulating the die stack wafer, the packaging stack including the TSV die 110 stacked on the die stack 22 can be flipped and attached to the package substrate 180 as shown in FIG. 2.

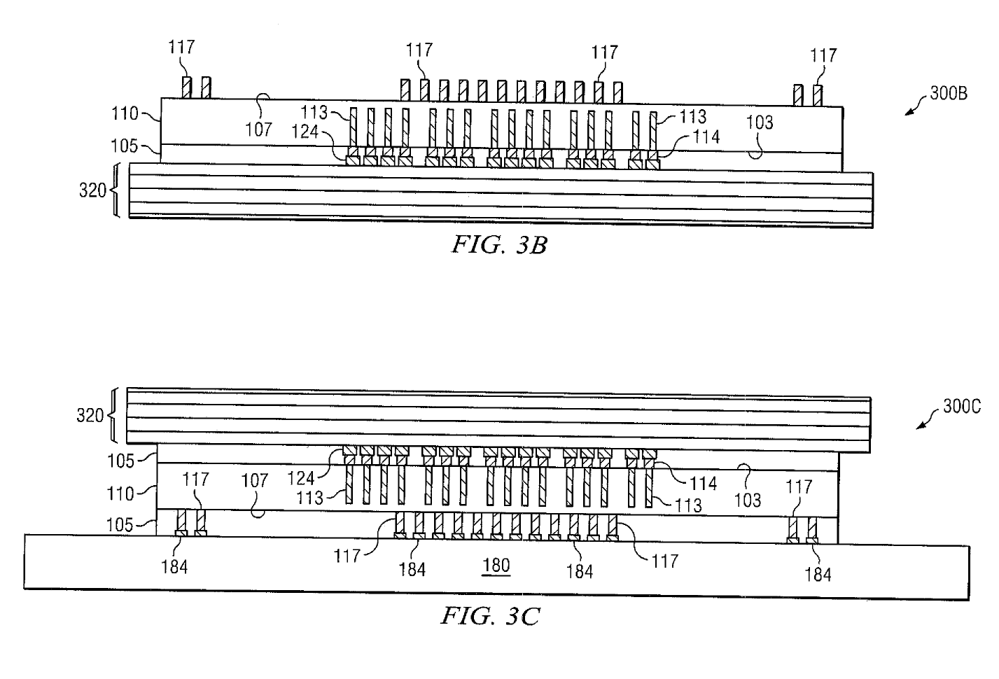

In embodiments, components packaged with TSV dies can include, for example, an IC component in a molded strip form. FIGS. 3A-3C depict an additional exemplary method for flip-chip packaging a TSV semiconductor die in accordance with various embodiments of the present teachings.

In FIG. 3A, an IC component molded strip, for example, a memory module molded strip 300A, can be provided to include a plurality of memory module pads or stacks 320. The TSV die 110 as shown in FIG. 1C can be, for example, a processor TSV die, and can be attached to a corresponding memory module stack 320. The attaching process can be performed as similarly described in FIG. 1D.

In embodiments, the exemplary processor TSV die can be provided by singulating a processor wafer. The processor wafer can include a plurality of dies with each die including a plurality of TSVs and with each die including a plurality of metal bumps on a bump-side. The processor wafer can then be thinned to expose the plurality of TSVs on a TSV-side of each die.

In FIG. 3B, each memory module stack 320 jointed with the TSV die 110 at its TSV-side 107 can be singulated from the memory module molded strip 300A, for example, by sawing through the memory module molded strip 300A.

In FIG. 3C, the TVS die 110 along with the attached memory module molded stack 320 can form a packaging stack and can then be flipped and attached to a package substrate 180 as similarly described in FIG. 1F.

In embodiments, underfill materials 105, for example, a capillary underfill, an underfill paste, or an underfill film, can be applied, for example, between the TSV-side of the exemplary processor TSV die 110 and the memory module stack 320 and/or between the bump-side of the exemplary processor TSV die 110 and the package substrate 180.

In this manner, by first forming a packaging stack including a TSV semiconductor die on a packaging component and then flip-chip packaging the TSV semiconductor die onto the package substrate, the thin TSV semiconductor die can be flip-chip packaged with reduced or eliminated warpage and mis-alignment as compared with conventional flip-chip packaging processes.

In various embodiments, depending on the specific IC devices and their processes, the flip-chip packaged TSV dies and/or the packaging stack can be molded with a mold compound. Any suitable mold compound known in the art can be used.

In various embodiments, a mother board, for example, a printed circuit board (PCB), can be attached to the package substrate on an opposing side of the packaging stack for an external communication.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” Further, in the discussion and claims herein, the term “about” indicates that the value listed may be somewhat altered, as long as the alteration does not result in nonconformance of the process or structure to the illustrated embodiment. Finally, “exemplary” indicates the description is used as an example, rather than implying that it is an ideal.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A flip-chip packaging method comprising:
providing a TSV semiconductor die comprising a bump-side and a TSV-side, wherein the bump-side comprises a plurality of conductive bumps and wherein the TSV-side exposes a plurality of through silicon vias (TSVs) in the TSV semiconductor die;
attaching the TSV-side of the TSV semiconductor die to a packaging component to form a packaging stack; and
flipping the packaging stack and attaching the bump-side of the TSV semiconductor die of the packaging stack to a package substrate.

2. The method of claim 1, wherein the packaging component comprises a semiconductor die, an IC (integrated circuit) stack, an IC molded strip, a passive component, a system-on-a-chip, a ball grid array (BGA) or a combination thereof.

3. The method of claim 1, wherein each of the semiconductor die and the package component comprises a microprocessor, a digital signal processor, a radio frequency chip, a MEMS chip, a memory, a microcontroller, or an application specific integrated circuit.

4. The method of claim 1 further comprising applying an underfill material between the TSV-side of the TSV semiconductor die and the packaging component, and between the bump-side of the TSV semiconductor die and the package substrate.

5. The method of claim 4, wherein the underfill material comprises an epoxy resin.

6. The method of claim 4, wherein the underfill material is applied as a capillary underfill, an underfill paste, or an underfill film.

7. The method of claim 1, wherein the packaging stack is formed by:
attaching the TSV-side of the TSV semiconductor die to a corresponding packaging component of a wafer that comprises a plurality of packaging components; and
singulating the wafer.

8. The method of claim 1, wherein attaching the TSV-side of the TSV semiconductor die to a packaging component comprises making a joint between the TSV semiconductor die and the packaging component by a process comprising a thermo-compression bonding or a solder reflow bonding.

9. The method of claim 1, wherein attaching the bump-side of the TSV semiconductor die to a package substrate comprises making a joint between the conductive bumps of TSV semiconductor die and the package substrate by a process comprising a thermo-compression bonding or a solder reflow bonding.

10. The method of claim 1 further comprising molding the TSV semiconductor die or the packaging stack with a mold compound after the packaging stack is attached to the package substrate.

11. The method of claim 1, wherein providing a TSV semiconductor die comprises:
providing a flip-chip TSV wafer; wherein the flip-chip TSV wafer comprises a plurality of TSV semiconductor dies;
forming a plurality of conductive bumps on one side of each TSV semiconductor die;
thinning the flip-chip TSV wafer from an opposing side of the conductive bumps to expose the TSVs in each TSV semiconductor die; and
singulating the flip-chip TSV wafer into a plurality of discrete TSV semiconductor dies by a process comprising a wafer sawing.

12. The method of claim 1, wherein each of the conductive bumps and TSVs comprises a metal selected from the group consisting of Cu, Pb, Sn, In, Ag, Au, Ni and a combination thereof.

13. The method of claim 1, wherein the package substrate is an organic substrate, a ceramic substrate, a glass epoxy substrate, a multilayer base substrate, or a bismaleimide triazine (BT) substrate.

14. The method of claim 1, wherein each TSV has a diameter of less than about 10 μm.

15. The method of claim 1, wherein the TSV semiconductor die comprises a TSV pitch of less than about 50 μm.

16. The method of claim 1, wherein the TSV semiconductor die comprises a TSV density of from about 100 to about 1000 TSVs per die.

17. A flip-chip packaging method comprising:
providing a processor TSV (through silicon via) die; wherein the processor TSV die comprises a bump-side having a plurality of metal bumps and a TSV-side exposing a plurality of TSVs burried therein;
attaching the TSV-side of the process TSV die to a corresponding memory module stack of a memory module molded strip;
applying an underfill material between the TSV-side of the processor TSV die and the memory module stack;
singulating the memory module molded strip to provide a packaging stack, wherein the packaging stack comprises the processor TSV die stacked on a singulated memory module stack; and
flipping the packaging stack and attaching the bump-side of the processor TSV die onto a package substrate.

18. The method of claim 17, further comprising applying an underfill material between the bump-side of the processor TSV die and the package substrate.

19. The method of claim 17, wherein providing a processor TSV die comprises:
providing a processor wafer comprising a plurality of processor TSV dies with each die comprising a plurality of TSVs;
forming the plurality of metal bumps on the bump-side of each processor TSV die;
thinning the processor wafer to expose the plurality of TSVs of each processor TSV die; and
singulating the processor wafer to provide the processor TSV die.

20. The method of claim 17, wherein the attachment between the TSV-side of the processor TSV die and the memory module stack or between the bump-side of the processor TSV die and the package substrate comprises a process of a thermo-compression bonding or a solder reflow bonding.
